(19) United States
(12) Patent Application Publication
(10) Pub. No.: US 2021/0101252 A1
(43) Pub. Date: Apr. 8, 2021

(54) METHOD OF GRINDING SUBSTRATE

(71) Applicant: DISCO CORPORATION, Tokyo (JP)

(72) Inventors: Hiroshi KUROKAWA, Tokyo (JP); Souichi MATSUBARA, Tokyo (JP)

(21) Appl. No.: 17/038,820

(22) Filed: Sep. 30, 2020

(30) Foreign Application Priority Data
Oct. 3, 2019 (JP) 2019-183133

(51) Int. Cl. B24B 41/06; H01L 33/00; B24B 7/22

(52) U.S. Cl. CPC B24B 41/068; B24B 7/228; H01L 33/0093

(57) ABSTRACT

A method of grinding a substrate includes grinding the substrate to a larger depth at an outer circumferential portion of the substrate than at a central portion of the substrate by keeping an annular grindstone assembly of a grinding unit and the substrate in abrasive contact with each other while a portion of a holding surface of a chuck table underlying an area of contact between the annular grindstone assembly and the substrate is lying not parallel to a grinding surface defined by a lower surface of the annular grindstone assembly, lifting the grinding unit to separate the annular grindstone assembly from the substrate, and, grinding the substrate by keeping again the annular grindstone assembly and the substrate in abrasive contact with each other by lowering the grinding unit while the portion of the holding surface is lying parallel to the grinding surface.

### BACKGROUND OF THE INVENTION

### Field of the Invention

The present invention relates to a method of grinding a substrate that is held on a holding surface of a chuck table.

### Description of the Related Art

Electronic appliances such as mobile phones incorporate optical device chips including light-emitting diodes (LEDs) or the like. For manufacturing optical device chips, an epitaxial growth layer of gallium nitride or the like is initially formed on the face side of a hard substrate that is made of sapphire, silicon carbide, or the like. Then, a plurality of projected dicing lines are established in a grid pattern on the face side of the epitaxial growth layer, demarcating a plurality of areas thereon, and a plurality of optical devices are formed respectively in the demarcated areas. Thereafter, a laser beam having a wavelength that is absorbable by or transmittable through the hard substrate is applied to a layered assembly of the hard substrate and the epitaxial growth layer along the projected dicing lines, dividing the layered assembly into a plurality of individual optical device chips.

In order to fabricate optical device chips that are lighter in weight, smaller in size, and higher in luminance, the hard substrate is sometimes thinned by grinding the reverse side thereof after the epitaxial growth layer has been formed on the face side of the hard substrate. A grinding apparatus is used to grind hard substrates. The grinding apparatus includes a spindle and an annular grinding wheel mounted on an end of the spindle. An annular array of grinding stones each having a segmental shape, for example, is disposed on a lower surface of the grinding wheel. A chuck table is disposed in a position opposite the lower surface of the grinding wheel.

For grinding the reverse side of the hard substrate, the chuck table holds the face side of the hard substrate such that the reverse side of the hard substrate is exposed upwardly. Then, the chuck table and the grinding wheel are rotated about their own central axes in a predetermined direction, and the grinding wheel is grinding-fed toward the chuck table, bringing the grinding stones into contact with the reverse side of the hard substrate. The hard substrate that is made of sapphire, silicon carbide, or the like is highly hard, and the reverse side of the hard substrate has been normally processed to a mirror finish. Consequently, the grinding stones may slip on the reverse side of the hard substrate, possibly failing to keep the grinding step in progress. An additional problem is that, in a case where the grinding stones slip on the reverse side of the hard substrate, the hard substrate may possibly be damaged due to a pressure that is applied from the grinding stones to the hard substrate as the grinding wheel is grinding-fed.

As an approach to solve the above problems, there is known a step of tilting a grinding surface that is defined by the lower surfaces of a plurality of grinding stones with respect to the reverse side of a hard substrate, thereby making the area of contact between the grinding stones and the hard substrate smaller than that in a case where the grinding surface is not tilted, so that the grinding stones are more likely to bite into the hard substrate (see, for example, JP 2011-206867A). This step is effective to restrain the grinding stones from slipping on the reverse side of the hard substrate. In the step, after the grinding stones have ground down the hard substrate by a predetermined thickness, and while the grinding stones and the hard substrate are being kept in contact with each other, i.e., while a grinding load is being imposed on the chuck table, the grinding surface is tilted back to a horizontal position. When the hard substrate is ground further by the grinding surface in the horizontal position, the hard substrate has smaller in-plane height irregularities, i.e., is finished to the higher thickness accuracy.

Instead of tilting the grinding surface with respect to the reverse side of the hard substrate, the reverse side of the hard substrate may be tilted with respect to the grinding surface (see, for example, JP 2011-206867A). For tilting the reverse side of the hard substrate, a tilt adjusting mechanism is used to adjust the tilt of the chuck table. When the tilt adjusting mechanism is used, it is necessary to tilt the chuck table while a grinding load is being imposed on the chuck table.

### SUMMARY OF THE INVENTION

However, changing the tilt of the chuck table while it is being subjected to the grinding load requires the tilt adjusting mechanism to be of very high rigidity. Furthermore, since the depth to which the hard substrate is ground per unit time varies when the tilt of the chuck table is changed while the chuck table is under the grinding load, various difficulties such as grinding faults, grinding stone chippings, or grinding apparatus failures tend to occur. The present invention has been made in view of the above problems. It is an object of the present invention to provide a method of grinding a substrate in a manner to lower the level of rigidity required of a tilt adjusting mechanism for tilting a chuck table and also to reduce the occurrence of grinding faults, compared with changing the tilt of the chuck table while it is being subjected to a grinding load.

In accordance with an aspect of the present invention, there is provided a method of grinding a substrate held on a holding surface of a chuck table with a grinding wheel while the chuck table and the grinding wheel are being rotated about their own central axes. The method of grinding a substrate includes a first grinding step of grinding the substrate to a larger depth at an outer circumferential portion of the substrate than at a central portion of the substrate by keeping an annular grindstone assembly of a grinding unit and the substrate in abrasive contact with each other while a portion of the holding surface underlying an area of contact between the annular grindstone assembly and the substrate is lying not parallel to a grinding surface defined by a lower surface of the annular grindstone assembly, the grinding unit including the grinding wheel that has an annular wheel base and the annular grindstone assembly disposed on a surface of the annular wheel base. The method of grinding a substrate also includes, after the first grinding step, a grinding unit lifting step of lifting the grinding unit to separate the annular grindstone assembly from the substrate, and, after the grinding unit lifting step, a second grinding step of grinding the substrate by keeping again the annular grindstone assembly and the substrate in abrasive contact with each other by lowering the grinding unit while the portion of the holding surface is lying parallel to the grinding surface.

In the grinding unit lifting step according to the aspect of the present invention, the grinding unit is lifted to move the annular grindstone assembly away from the substrate. Therefore, the chuck table that supports the workpiece thereon and hence the tilt adjusting mechanism that makes the portion of the holding surface lie parallel to or not parallel to the grinding surface are released from any load from the grinding unit. Inasmuch as the tilt adjusting mechanism is actuated to tilt the chuck table while under no load from the grinding unit after the grinding unit lifting step, the level of rigidity required of the tilt adjusting mechanism is lowered compared with changing the tilt of the chuck table while it is being subjected to a grinding load. Furthermore, the occurrence of various difficulties such as grinding faults, grinding stone chippings, or grinding apparatus failures is reduced.

The above and other objects, features and advantages of the present invention and the manner of realizing them will become more apparent, and the invention itself will best be understood from a study of the following description and an appended claim with reference to the attached drawings showing a preferred embodiment of the invention.

### BRIEF DESCRIPTION OF THE DRAWINGS

FIG. 1 is a side elevational view, partly in cross section, of a grinding apparatus that carries out a method of grinding a substrate according to an embodiment of the present invention;

FIG. 2 is a perspective view of a workpiece held on a holding surface and a grinding unit;

FIG. 3A is a side elevational view, partly in cross section, illustrating a first grinding step of the method of grinding a substrate;

FIG. 3B is a plan view of an upper surface of the workpiece and a grinding wheel in the first grinding step;

FIG. 4 is a side elevational view, partly in cross section, illustrating a grinding unit lifting step of the method of grinding a substrate;

FIG. 5A is a side elevational view, partly in cross section, illustrating the manner in which the tilt of a rotational axis is changed;

FIG. 5B is a side elevational view, partly in cross section, illustrating the manner in which the grinding unit is lowered in a second grinding step; and

FIG. 6 is a flowchart of the method of grinding a substrate.

### DETAILED DESCRIPTION OF THE PREFERRED EMBODIMENT

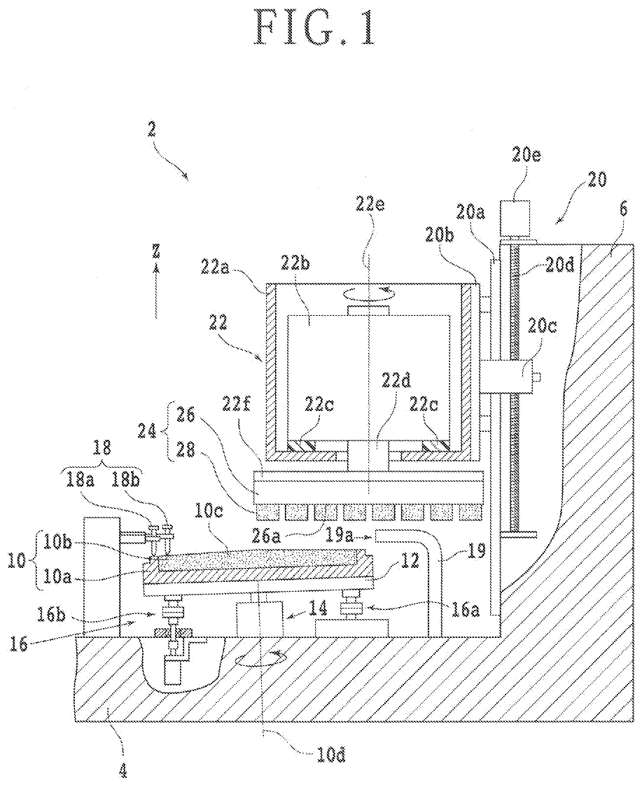

A method of grinding a substrate according to a preferred embodiment of the present invention will be described in detail below with reference to the accompanying drawings. First, a grinding apparatus that carries out the method of grinding a substrate according to the embodiment will be described below. FIG. 1 illustrates the grinding apparatus, which is denoted by 2, in side elevation partly in cross section. As illustrated in FIG. 1, the grinding apparatus 2 has a base 4 substantially in the shape of a rectangular parallelepiped that supports a plurality of components of the grinding apparatus 2. The grinding apparatus 2 includes a substantially disk-shaped chuck table 10 rotatably mounted on the base 4. The chuck table 10 has a frame 10a made of ceramic. The frame 10a has a fluid channel (not illustrated) that is defined therein and has an end connected to a suction source (not illustrated) such as an ejector.

The frame 10a has a recess defined as a disk-shaped space in an upper surface thereof. A substantially disk-shaped porous plate 10b is fixedly mounted in the recess. The porous plate 10b has a flat circular lower surface and a conical upper surface for holding a workpiece including a substrate thereon. The other end of the fluid channel defined in the frame 10a is connected to the lower surface of the porous plate 10b. When the suction source is actuated, it produces a negative pressure that is transmitted through the fluid channel and the porous plate 10b itself and acts on the upper surface of the porous plate 10b. The workpiece held on the upper surface of the porous plate 10b is thus attracted and held under suction thereon. Therefore, the upper surface of the porous plate 10b functions as a holding surface 10c.

The chuck table 10 has a lower surface coupled to a disk-shaped table base 12 having a lower surface coupled to an actuating mechanism 14 such as an electric motor. The actuating mechanism 14 is operatively coupled to the chuck table 10 through the table base 12. When the actuating mechanism 14 is operated, the chuck table 10 is rotated about a predetermined rotational axis 10d. The lower surface of the table base 12 is also coupled to a tilt adjusting mechanism 16 having a single fixed support member 16a and two movable support members 16b. The single fixed support member 16a and the two movable support members 16b are coupled to the table base 12 at respective positions that are annularly spaced apart from each other by 120 degrees in the circumferential directions of the table base 12. In FIG. 1, one of the two movable support members 16b is illustrated, whereas the other is omitted from illustration.

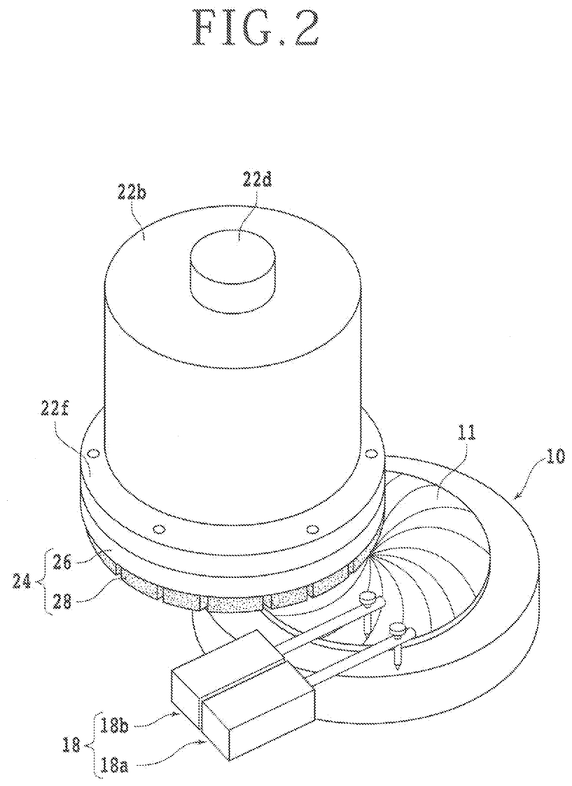

The fixed support member 16a has an upper end whose height is fixed. On the other hand, the movable support members 16b have upper ends whose heights are vertically variable. By adjusting the heights of the upper ends of the movable support members 16b, the rotational axis 10d of the chuck table 10 is tilted with respect to vertical directions, i.e., Z-axis directions. A thickness measuring unit 18 is disposed sideways of the chuck table 10. The thickness measuring unit 18 has a first height measuring element 18a disposed over the frame 10a and a second height measuring element 18b disposed over the porous plate 10b. The height of the upper surface of the frame 10a is measured by the first height measuring element 18a, and the height of the upper surface of the workpiece, which is denoted by 11 in FIG. 2, held on the holding surface 10c of the porous plate 10b is measured by the second height measuring element 18b. The thickness of the workpiece 11 is calculated by calculating the difference between the height of the upper surface of the workpiece 11 and the height of the upper surface of the frame 10a.

A grinding fluid supply unit 19 is disposed sideways of the chuck table 10 at a position remote from the thickness measuring unit 18. The grinding fluid supply unit 19 is connected to a grinding fluid supply source (not illustrated) that stores therein a grinding fluid such as pure water. The grinding fluid supply unit 19 includes a first pipe extending vertically from the base 4 and a second pipe connected to an upper end of the first pipe and bent through approximately 90 degrees from the upper end of the first pipe toward the rotational axis 10d of the chuck table 10. A nozzle 19a is disposed on the distal end of the second pipe.

A column 6 in the shape of rectangular parallelepiped is erected from the base 4 at a position that is spaced from the chuck table 10 across the grinding fluid supply unit 19. A grinding feed unit 20 is mounted on a front side of the column 6 that faces the grinding fluid supply unit 19. The grinding feed unit 20 has a pair of parallel guide rails 20a extending vertically in the Z-axis directions along the column 6. The guide rails 20a are fixed to the front side of the column 6. A movable plate 20b is slidably mounted on the guide rails 20a and has a nut 20c fixedly mounted on a rear surface thereof.

The nut 20c is threaded over a ball screw 20d mounted in the column 6 and extending vertically along the Z-axis directions. The ball screw 20d is rotatable about its own central axis. A stepping motor 20e is coupled to an upper end of the ball screw 20d. When the stepping motor 20e is energized, it rotates the ball screw 20d about its own central axis, causing the nut 20c to move the movable plate 20b along the guide rails 20a. The grinding apparatus 2 includes a grinding unit 22 mounted on a front surface of the movable plate 20b. The grinding unit 22 has a hollow cylindrical holder 22a fixed to the front surface of the movable plate 20b.

The grinding unit 22 includes a spindle housing 22b disposed in the holder 22a. An annular cushioning member 22c made of rubber or the like is disposed on a lower surface of the spindle housing 22b. The spindle housing 22b is supported on the bottom of the holder 22a by the cushioning member 22c. A spindle 22d that has a portion housed in the spindle housing 22b is rotatably supported on the spindle housing 22b. The spindle 22d has an upper end coupled to a rotary actuator (not illustrated) such as an electric motor. When the rotary actuator is energized, the spindle 22d is rotated thereby about a rotational axis 22e that is coaxial with the spindle 22d, the spindle housing 22b, and the holder 22a.

The spindle 22d has a lower end portion extending downwardly through the bottom of the holder 22a. An annular wheel mount 22f has an upper surface coupled to the lower end of the spindle 22d. The wheel mount 22f has a lower surface on which an upper surface of an annular grinding wheel 24 is mounted. The grinding wheel 24 has an annular wheel base 26 made of a metal such as aluminum and having a diameter of approximately 200 mm, for example. The upper surface of the wheel base 26 is coupled to the lower surface of the wheel mount 22f. The grinding wheel 24 is thus mounted on the spindle 22d by the wheel mount 22f.

The wheel base 26 has an annular lower surface 26a on which a plurality of grinding stones 28, i.e., an annular grindstone assembly, is disposed. Each of the grinding stones 28 is formed by mixing abrasive grains of diamond, cubic boron nitride (cBN), or the like with a binder such as a vitrified binder or a resinoid and sintering the mixture. According to the present embodiment, the grinding stones 28 are disposed in an annular array, i.e., a segmental array. Alternatively, the grinding stones 28 may be replaced with an annular grinding stone or annular grindstone assembly in a continuous array.

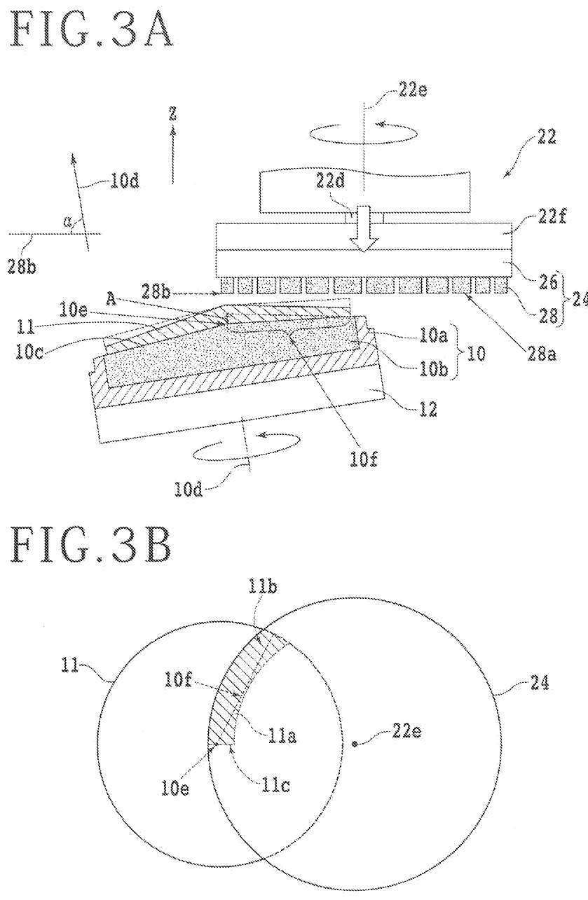

The grinding wheel 24 is disposed above the chuck table 10 such that a portion of the annular lower surface 26a is positioned over a rotational center 10e of the chuck table 10 where the holding surface 10c and the rotational axis 10d intersect with each other (see FIGS. 3A through 5A). The grinding wheel 24 is of an annular shape, and the grinding fluid supply unit 19 is positioned within the annular grinding wheel 24. Therefore, when the grinding apparatus 2 is in operation to grind the workpiece 11, the grinding wheel 24 and the grinding fluid supply unit 19 are kept out of physical interference with each other.

Next, the workpiece 11 held on the chuck table 10 will be described below. FIG. 2 illustrates, in perspective, the workpiece 11 held on the holding surface 10c and the grinding unit 22. The workpiece 11 is a layered body having a hard substrate made of silicon carbide (SiC) and an epitaxial growth layer made of gallium nitride (GaN) or the like on a face side of the hard substrate. The epitaxial growth layer has a grid of projected dicing lines established on a face side thereof and demarcating a plurality of areas thereon with respective optical devices formed therein. A protective tape (not illustrated) made of a resin is affixed to the face side of the epitaxial growth layer.

When the face side of the epitaxial growth layer, i.e., the face side of the workpiece 11, is held on the holding surface 10c, a reverse side of the hard substrate is exposed upwardly, i.e., a reverse side of the workpiece 11 is exposed upwardly. At this time, the workpiece 11 is elastically deformed to match the conical holding surface 10c. While the chuck table 10 with the workpiece 11 held on the holding surface 10c and the grinding wheel 24 are being rotated about their own central axes in the same direction, the grinding unit 22 is grinding-fed, i.e., moved downwardly, to press the grinding stones 28 against the workpiece 11, causing the grinding stones 28 to grind the reverse side of the hard substrate.

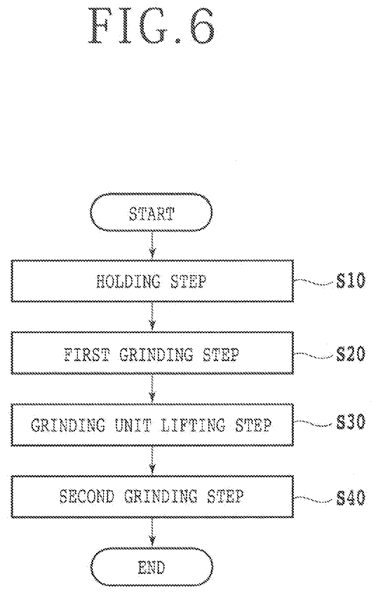

The method of grinding a substrate according to the present embodiment, i.e., the method of grinding the workpiece 11, will now be described below. FIG. 6 is a flowchart of the method of grinding a substrate according to the present embodiment. First, the protective tape is affixed to the face side of the epitaxial growth layer, and then, the face side of the workpiece 11 is held on the holding surface 10c in holding step S10. Next, first grinding step S20 is carried out. FIG. 3A illustrates first grinding step S20 in side elevation partly in cross section. FIG. 3B illustrates, in plan, the upper surface of the workpiece 11 and the grinding wheel 24 in first grinding step S20.

In first grinding step S20, the heights of the upper ends of the movable support members 16b are adjusted such that the rotational axis 10d of the chuck table 10 is tilted with respect to a grinding surface 28b defined by respective lower surfaces 28a of the grinding stones 28 by a first angle of a. With the rotational axis 10d of the chuck table 10 being thus tilted by the first angle of a, a portion 10f, e.g., an area corresponding to the generator of a cone, of the holding surface 10c underlying an area 11a, i.e., an arcuate area having a predetermined width illustrated hatched in FIG. 3B, of contact between the grinding stones 28 and the workpiece 11 lies not parallel to the grinding surface 28b. More specifically, the rotational center 10e, i.e., the vertex of the conical holding surface 10c, is spaced a distance A of 5 μm, for example, downwardly from the outermost circumference of the portion 10f of the holding surface 10c positioned directly below the grinding wheel 24, thereby keeping the portion 10f not parallel to the grinding surface 28b.

Then, the chuck table 10 is rotated at 60 rpm, for example, and the spindle 22d is rotated at 2500 rpm, for example. At the same time, the grinding unit 22 is grinding-fed, i.e., lowered, at a predetermined processing-feed speed in the range of 0.1 μm/s to 0.5 μm/s, e.g., at a processing-feed speed of 0.3 μm/s. At this time, the portion 10f of the holding surface 10c and the grinding surface 28b are maintained not parallel to each other. In addition, the nozzle 19a supplies a grinding fluid to a region where the grinding stones 28 and the workpiece 11 are to be kept in contact with each other. The grinding stones 28 and the reverse side of the workpiece 11 are then brought into abrasive contact with each other, grinding the reverse side of the workpiece 11. In grinding step S20, the grinding stones 28 grind the reverse side of the workpiece 11 to remove a thickness ranging from approximately 10 μm to 20 μm at the outermost circumference thereof.

In first grinding step S20, since the portion 10f of the holding surface 10c lies not parallel to the grinding surface 28b, the grinding stones 28 are more likely to bite into the workpiece 11. Accordingly, the grinding stones 28 are retrained from slipping on the reverse side of the workpiece 11. In first grinding step S20, furthermore, as the outermost circumference of the portion 10f of the holding surface 10c is spaced upwardly from the rotational center 10e by the distance A, the workpiece 11 is ground to a larger depth at an outer circumferential portion 11b than at a central portion 11c in the area 11a of contact between the grinding stones 28 and the workpiece 11. The grinding surface 28b is defined by the lower surface 28a of one or more of the grinding stones 28 when the grinding wheel 24 is rotated about the rotational axis 22e. The grinding surface 28b may be defined by the lower surface 28a of one of the grinding stones 28 that protrudes most downwardly, by the lower surfaces 28a of some of the grinding stones 28 that protrude most downwardly, or by the lower surfaces 28a of plural grinding stones 28 that lie at the same height.

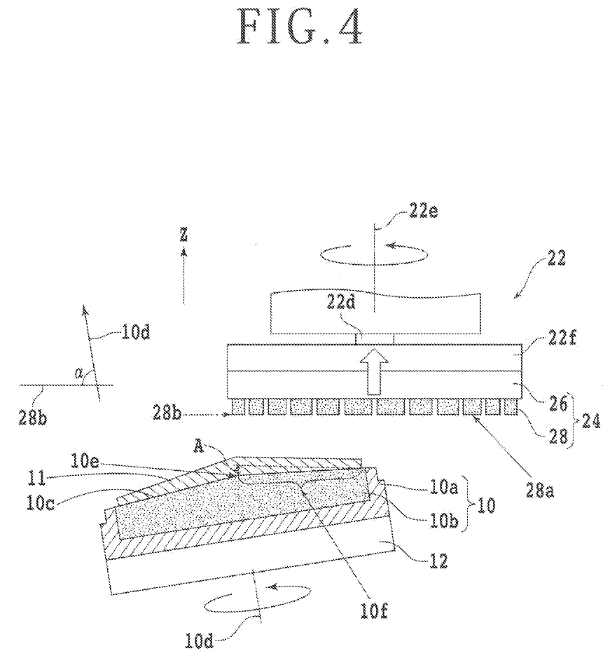

After first grinding step S20, the grinding unit 22 is lifted to separate the grinding stones 28 from the reverse side of the workpiece 11 in grinding unit lifting step S30. In grinding unit lifting step S30, the grinding surface 28b is lifted by a distance of 10 μm, for example. FIG. 4 illustrates grinding unit lifting step S30 in side elevation partly in cross section. In grinding unit lifting step S30, since the grinding unit 22 is lifted away from the workpiece 11, the chuck table 10 that supports the workpiece 11 thereon and hence the tilt adjusting mechanism 16 are released from any load from the grinding unit 22.

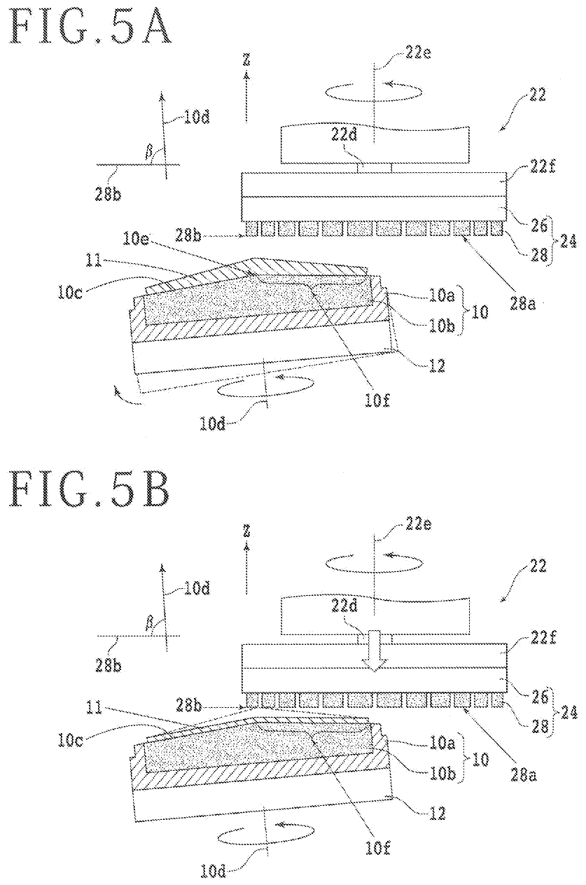

After grinding unit lifting step S30, the heights of the upper ends of the movable support members 16b are adjusted to tilt the rotational axis 10d of the chuck table 10 with respect to the grinding surface 28b by a second angle of β that is larger than the first angle of a, making the portion 10f of the holding surface 10c parallel to the grinding surface 28b. FIG. 5A illustrates, in side elevation partly in cross section, the manner in which the tilt of the rotational axis 10d is changed. Inasmuch as the tilt adjusting mechanism 16 for tilting the chuck table 10 is actuated to tilt the chuck table 10 while under no load from the grinding unit 22 after grinding unit lifting step S30, the level of rigidity required of the tilt adjusting mechanism 16 for tilting the chuck table 10 is lowered compared with changing the tilt of the chuck table while it is being subjected to a grinding load. Consequently, the tilt adjusting mechanism 16 may be of conventional nature. According to the present embodiment, furthermore, since the tilt of the chuck table 10 is not changed while it is under a grinding load, the depth to which the workpiece 11 is ground per unit time remains unchanged. Therefore, the occurrence of various difficulties such as grinding faults, grinding stone chippings, or grinding apparatus failures is reduced. While the portion 10f of the holding surface 10c and the grinding surface 28b are parallel to each other, the grinding unit 22 is lowered to bring the grinding stones 28 and the workpiece 11 into abrasive contact with each other, grinding the workpiece 11 in second grinding step S40. FIG. 5B illustrates, in side elevation partly in cross section, the manner in which the grinding unit 22 is lowered in second grinding step S40.

In second grinding step S40, the chuck table 10 is rotated at 60 rpm, for example, and the spindle 22d is rotated at 2500 rpm, for example. At the same time, the grinding unit 22 is grinding-fed, i.e., lowered, at a predetermined processing-feed speed in the range of 0.1 μm/s to 0.5 μm/s, e.g., at a processing-feed speed of 0.3 μm/s. In addition, the nozzle 19a supplies a grinding fluid to a region where the grinding stones 28 and the workpiece 11 are kept in contact with each other. The workpiece 11 is now ground until the hard substrate thereof is thinned to a predetermined thickness. In second grinding step S40, the workpiece 11 is ground while the portion 10f of the holding surface 10c is being kept parallel to the grinding surface 28b. This guarantees that the workpiece 11 will be finished to the desired thickness accuracy. Furthermore, in second grinding step S40, since the workpiece 11 has been ground to the larger depth at the outer circumferential portion 11b than at the central portion 11c, the grinding stones 28 are more likely to bite into the central portion 11c of the workpiece 11. According to the present embodiment, the level of rigidity required of the tilt adjusting mechanism 16 for tilting the chuck table 10 is lowered compared with changing the tilt of the chuck table while it is being subjected to a grinding load, and the occurrence of grinding faults is reduced. In addition, the grinding stones 28 are more likely to bite into the workpiece 11, and it is guaranteed that the workpiece 11 will be finished to the desired thickness accuracy.

Changes and modifications may be made in the structural details and method details according to the embodiment without departing from the scope of the invention. For example, the hard substrate used in the workpiece 11 may be a sapphire substrate or a substrate made of a material having a Mohs hardness of 9 or more or a material having a Vickers hardness HV of 2200 or more. The workpiece 11 may alternatively include a substrate made of silicon that is less hard than the hard substrate. For example, inasmuch as wafers having relatively large surface irregularities such as as-sliced wafers are likely to endure larger grinding loads, it is effective to apply the method of grinding a substrate according to the present invention to those wafers.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A method of grinding a substrate held on a holding surface of a chuck table with a grinding wheel while the chuck table and the grinding wheel are being rotated about their own central axes, comprising:
a first grinding step of grinding the substrate to a larger depth at an outer circumferential portion of the substrate than at a central portion of the substrate by keeping an annular grindstone assembly of a grinding unit and the substrate in abrasive contact with each other while a portion of the holding surface underlying an area of contact between the annular grindstone assembly and the substrate is lying not parallel to a grinding surface defined by a lower surface of the annular grindstone assembly, the grinding unit including the grinding wheel that has an annular wheel base and the annular grindstone assembly disposed on a surface of the annular wheel base;
after the first grinding step, a grinding unit lifting step of lifting the grinding unit to separate the annular grindstone assembly from the substrate; and
after the grinding unit lifting step, a second grinding step of grinding the substrate by keeping again the annular grindstone assembly and the substrate in abrasive contact with each other by lowering the grinding unit while the portion of the holding surface is lying parallel to the grinding surface.
